(19) United States
(12) Patent Application Publication
(10) Pub. No.: US 2004/0203242 A1
(43) Pub. Date: Oct. 14, 2004

(54) System and method for performing a metal layer RIE process

(76) Inventors: George Stojakovic, Hopewell Junction, NY (US); Matthias Lipinski, Dresden (DE)

Correspondence Address: SHAW PITTMAN LLP, 1650 Tysons Boulevard, McLean, VA, 22102, US

(21) Appl. No.: 10/411,279

(22) Filed: Apr. 11, 2003

(51) Int. Cl. H01L 21/302; H01L 21/461

(52) U.S. Cl. 438/690

(57) ABSTRACT

A method and a system for performing a metal reactive ion etching (RIE) process is disclosed. The metal RIE process comprises at least three steps: a metal RIE step, a stripping step and a wet cleaning step. The metal RIE step and the stripping step are carried out in a main reactive chamber.

### BACKGROUND

1. Field of the Invention

The present invention generally relates to methods and systems for etching a metal layer as part of a semiconductor device manufacturing process and more particularly, to a method and system for removing the undesired residues produced in a metal RIE (reactive ion etching) process.

2. Background of the Invention

In the fabrication of semiconductor integrated circuits, a metal wiring process is usually carried out on a wafer upon which a number of semiconductor devices have been formed to form conductive paths between the devices. A metal layer is typically blanket deposited on the surface of the wafer. Using an appropriate photo-resist mask, portions of the metal layer are then etched away, leaving behind metal lines and features. Generally, aluminum (Al) or aluminum alloy is most commonly used in the interconnection metallurgy of the integrated circuits. For the purpose of simplicity, Al is used to represent metal lines in the description hereinafter.

As the density of the integrated circuits increases, the width of the metal line and the space therebetween shrink accordingly. In response to the shrinking of integrated circuits, a variety of techniques have been developed to properly etch the metal lines. A number of approaches for patterning the metal lines on the wafer have also been developed in conjunction with the enhanced etching techniques to obtain a better etching result.

In the past, patterning the metal lines was performed by a photolithography process. However, as the line widths being patterned are reduced, it becomes difficult to manufacture fine patterns using conventional photoresist patterning, because the effects of light reflection from a metal layer beneath the photo-resist layer increase dramatically in proportion to the reduced line width. Therefore, to reduce the light reflection effects, one recent approach for patterning metal lines is to deposit an anti-reflective coating on the photo-resist layer before forming photo-resist patterns via photolithography. The anti-reflective coating technique provides many benefits for micro lithography applications, including standing wave reduction, reflective notching reduction, elimination of back scattered light from a grainy substrate, and most recently, elimination of substrate chemicals interacting with a chemically-amplified resist system.

FIGS. 1A-1C are cross-sectional views showing a patterning process of the Al layer, in which FIGS. 1A and 1B illustrate patterning the photo-resist layer on the Al layer by applying an anti-reflective coating approach, as described below.

FIG. 1C illustrates that metal lines are formed by a metal etching process. The metal lines are patterned according to the photo-resist patterns as in FIGS. 1A and 1B.

In FIG. 1A, a metal layer 12, such as Al, is deposited on an insulated layer II which covers the surface of a wafer 10. Next, an anti-reflection coating (ARC) 13 is formed on the Al layer 12 by, for example, a plasma enhanced CVD (PECVD) process. A photoresist layer 14 is then deposited on the ARC 13. During the photolithography process, a light 16 from a light source (not shown) passes through transparent areas 17 of a mask 15 to irradiate selected portions of the photoresist layer 14.

As shown in FIG. 1B, after the light exposure, photo-resist patterns 18 of the photoresist 14 are formed. As described above, due to the benefits of the ARC 13, the photoresist patterns 18 are well formed. The wafer is then transferred to an Al RIE chamber for performing ARC open etching and Al line etching. Alternatively, the ARC open etching can be performed in a separate plasma chamber. After the ARC open etching is completed, the wafer is then transferred to the Al RIE chamber for etching the Al layer. In either way, after the Al line etching, Al lines are formed on a substrate of the wafer, as shown in FIG. 1C.

Typically, techniques used for metal etching include wet etching and dry plasma etching. Wet etching processes, however, are generally inadequate for defining features less than 3 μm due to its isotropic nature. Therefore, wet plasma etching processes are not viable for forming Al lines for modern semiconductor applications. Dry plasma etching processes are considered to be a better choice and particularly, reactive ion etching (RIE) processes have been thought to best meet the requirements for modern semiconductor devices. Generally, RIE processes comprise three basic steps: an Al RIE step, a stripping step and a wet clean step. The three steps are usually carried out in a Al RIE tool, which will be described next with reference to FIG. 2.

FIG. 2 is a partial schematic diagram of an Al RIE tool 10. As shown, the Al RIE tool 10 comprises a main reactive chamber 20 for performing the Al RIE step, a second chamber 30 for stripping resist materials and residues by-produced in the Al RIE step and a third chamber 40 for performing the wet-cleaning step. As shown, those three chambers are connected together in a specific order and are communicated with each other by control of valves 120 and 140. For example, the second chamber 30 is attached to the main reactive chamber 20 via valve 120 which, in turn, is attached with the third chamber 40 via valve 140. Valves 120 and 140 are open when a wafer is transferred from the main reactive chamber 20 into the second chamber 30 and from the second chamber 30 into the third chamber 40, respectively.

After the photoresist patterns are manufactured by, for example, the method described in FIGS. 1A and 1B, a wafer is first transferred to the main reactive chamber 20 for etching ARC layer 13 and the Al layer 12. As shown in FIG. 2, process gases 205 are introduced into the reactive chamber 20 through an inlet pipe 207. The amount of gases 205 flowing into the chamber 20 is controlled by a valve 209. Within the reactive chamber 20, a plasma reactor is provided for processing the process gases 205 into plasma 221. The exemplary reactive reactor shown in FIG. 2 is an inductively coupled plasma (“ICP”) reactor. The ICP plasma reactor includes an electrostatic chuck (ESC) 21 for receiving a wafer 50 that comprises photoresist patterns on the surface as described with reference to FIGS. 1A and 1B. The plasma reactor further includes a coil 22 wound outside a dielectric plate 23. The coil 22 and ESC 21 form a first electrode and a second electrode, respectively, so that the reactive plasma 221 is generated between the two electrodes. The chamber 20 further includes a vacuum pump 223 for keeping a pressure within the chamber 20 as low as possible, for example, 3 mTorr. The low pressure of chamber 20 helps to reduce the possibility of forming moisture in the chamber 20.

During the Al RIE step, a top supply power 217 and a bias supply power 219 may be supplied to the coil 22 and the ESC 21, respectively. Generally, the top supply power 217 can detenmine a concentration of reactive ions in the plasma 221, and the bias supply power 219 can detennine energy of the reactive ions when they hit the wafer 50. The reactive ions of the plasma 221 thus reacts with portions of the Al layer on the wafer 50, which are not covered by photo-resist patterns. The Al layer on these portions is etched away accordingly. Thus, Al lines 25 are formed, as shown in FIG. 1C.

Conventionally, the etching of the aluminum-containing metal layer is accomplished in the reactive chamber by using etching source gases, for example, such as Cl₂/BCl₃, Cl₂/HCI, Cl₂/N₂, and the like. In these gases, the chemical species contributing as a main etchant in the RIE process are chlorine radicals (Cl), because the chlorine radicals are voluntary and cause the etching reaction quickly. The chlorine radicals after the RIE process, however, will cause polymers formed on the photo-resist and sidewalls of the aluminum lines. The polymers contain organic materials redeposited during the Al RIE etching step and a nontrivial amount of chlorine and/or chlorine-containing compounds from the etching source gas. The polymers are shown in FIG. 1C as a reference number 19. As known in the art, the chlorine and/or chlorine-containing compounds causes corrosion of the aluminum lines once they contact with the atmosphere containing O₂/H₂O. Therefore, in order to avoid corrosion, these chlorine compounds are removed by first stripping the polymer and resist materials including ARC 13 and photoresist 14 (which will be referred to “resist materials” in the description hereinafter) in a plasma in the second chamber 30 and secondly applying a wet clean in the third chamber 40.

The description of the subsequent stripping step and the wet clean steps will now be described with reference to FIG. 3, which is a flow chart of a conventional Al RIE process.

Steps 301-303 describe depositing a metal layer on a substrate of a semiconductor wafer, depositing an ARC on the metal layer, depositing a photo-resist layer and forming photo-resist patterns, respectively, as described above with reference to FIGS. 1A and 1B. Next, in step 304, the wafer with the photo-resist patterns is transferred to the main reactive chamber 20 for an RIE step. As described above, the chemical material used to etch the metal layer in the Al RIE step is selectively a Cl-based gas.

As mentioned above, during and after the RIE process, polymers composed of Cl-containing residues form on the sidewalls of the metal lines formed by the RIE process. The polymers contain chlorine and chlorine compounds, which corrode the metal lines.

In step 305, conventionally, these chlorine species are removed by first stripping the remaining resist materials (such the remaining ARC layer and photoresist) in the second chamber 30 which is attached to the main reactive chamber 20. Usually, a dry ashing process is used under plasma assisted conditions where oxygen radicals and ions generated in the plasma reacts with organic material included in the resist materials. As illustrated in FIG. 2, the second chamber 30 comprises a gas inlet 301 to introduce gases for stripping the resist materials and the polymer into the chamber 30. Conventionally, the resist materials and polymer removal step can be performed by at least two methods. The first method includes an ashing process using a mixed gas containing a fluorine (F) gas and O₂ gas to remove the resist materials and polymers. The second method performs the ashing process by using a plasma of a mixed gas, which contains hydrogen and oxygen (an H and O containing gas), such as CH₃OH and an O₂ gas. Both of the stripping methods are carried out in the second chamber 30.

In step 306, after stripping the resist materials and polymers, the wafer is transferred to a third chamber 40 for wet cleaning. After the wet clean step, the wafer is dried out by a spin dryer. At this point, the removal of chlorine residues is complete.

The above-described process is designed for use with Al RIE tools that have been commonly utilized for performing an RIE process. Such Al RIE tools are often manufactured by LAM research, a leading manufacturer, and are designed to perform the RIE step, the stripping step and the wet clean step in three separate chambers. Due to this design, semiconductor device manufacturers are required to purchase an Al RIE tool composed of all three chambers. Furthermore, the process time for the Al RIE step and stripping step are different. Usually, it takes longer to perform the stripping step than the Al RIE step. Therefore, when a wafer of which a Al RIE step is completed cannot be transferred to the stripping chamber until the stripping process of a previous wafer is completed. During this time, the main chamber is sitting idle and cannot be used for the operation that it is intended to be used for.

Furthermore, the pressure required in the RIE chamber is far lower than that required in the stripping chamber. As the pressure increases in the stripping chamber, the water concentration (i.e., humidity) formed in the chamber increases. Therefore, in the separate stripping chamber, there is always a higher chance that oxygen or H₂O can react with the chlorine-containing residues than in the main chamber. Therefore, a corrosion to the Al lines cannot be completely avoided.

A method and a system for improving the above-mentioned process are thus desirable.

### SUMMARY OF THE INVENTION

The present invention provides a method for processing Al RIE and performing stripping steps in a main chamber, thereby reducing the cost of the RIE tools.

In accordance with an embodiment of the present invention, a method for performing an Al RIE process comprises reactive-ion etching a metal layer formed on a semiconductor wafer in a main reactive chamber. Portions of the metal layer are covered with photoresist patterns so that after the reactive-ion etching, metal lines are formed on the wafer and by-product residues generated during the etching are formed on top of the photoresist patterns and side walls of the metal lines. The method comprises additional step of stripping the photoresistor patterns and the by-product residues in the main reactive chamber.

In accordance with a further embodiment of the present invention, a gas mixture containing Ar/O₂ mixture is introduced into the main reactive chamber for used in the stripping step.

In accordance with a still embodiment of the present invention, a stripping step is performed by introducing a gas mixture containing Ar/O₂ with combinations of different ratios into a main reactive chamber, along with appropriate controls of the pressure in the main reactive chamber and supply powers to the main reactive chamber.

The present invention also provides a system for performing a RIE process. The system comprises a main reactive chamber where at least a metal RIE step and a stripping step are both carried out.

In accordance with one embodiment of the present invention, a system for performing a metal reactive ion etching process comprises a main reactive chamber for performing a metal etching step and a stripping step for a wafer with a metal layer and photoresist patterns on a surface of the metal layer and at least one gas inlet adapted to the main reactive chamber for introducing reactive gases used for the metal etching step and the stripping step.

In accordance with another embodiment of the present invention, the system further comprises a pair of electrodes composed of a top electrode and a bottom electrode in a form of an electrostatic chuck. Reactive gases introduced from at least one inlet passes through the pair of electrodes so that reactive ions are generated through the pair of electrodes to attack the wafer rested on the platform. During a stripping step, a top power supply provides a first power to the top electrode to determine an ion concentration of the reactive ions and a bias power supply provides a second power to the bottom electrode to determine a moving direction of the reactive ions.

### BRIEF DESCRIPTION OF THE DRAWINGS

FIGS. 1A-1C are cross-sectional views showing a patterning process of the Al layer, in which:

FIGS. 1A and 1B illustrate patterning a photoresist on the Al layer by applying an anti-reflective coating, and

FIG. 1C illustrates Al lines formed after an Al RIE step.

FIG. 2 is a schematic diagram of a portion of an Al RIE tool.

FIG. 3 is a flow chart of an Al RIE process.

FIG. 4 is a flow chart of an Al RIE process in accordance with an embodiment of the present invention.

### DETAILED DESCRIPTION OF THE PREFERRED EMBODIMENT

Hereinafter, preferred embodiments of the present invention will be described in detail with reference to the attached drawings. This invention may be embodied in many different forms and should not be construed as being limited to the embodiments set forth herein.

The present invention relates to a method and system for performing an RIE process in which steps for stripping resist materials and polymer residues are carried out in a main reactive chamber along with a metal RIE process. The present invention also relates to a system comprising a main reactive chamber configured such that the step for stripping resist materials and polymer residues are both carried out in the same chamber.

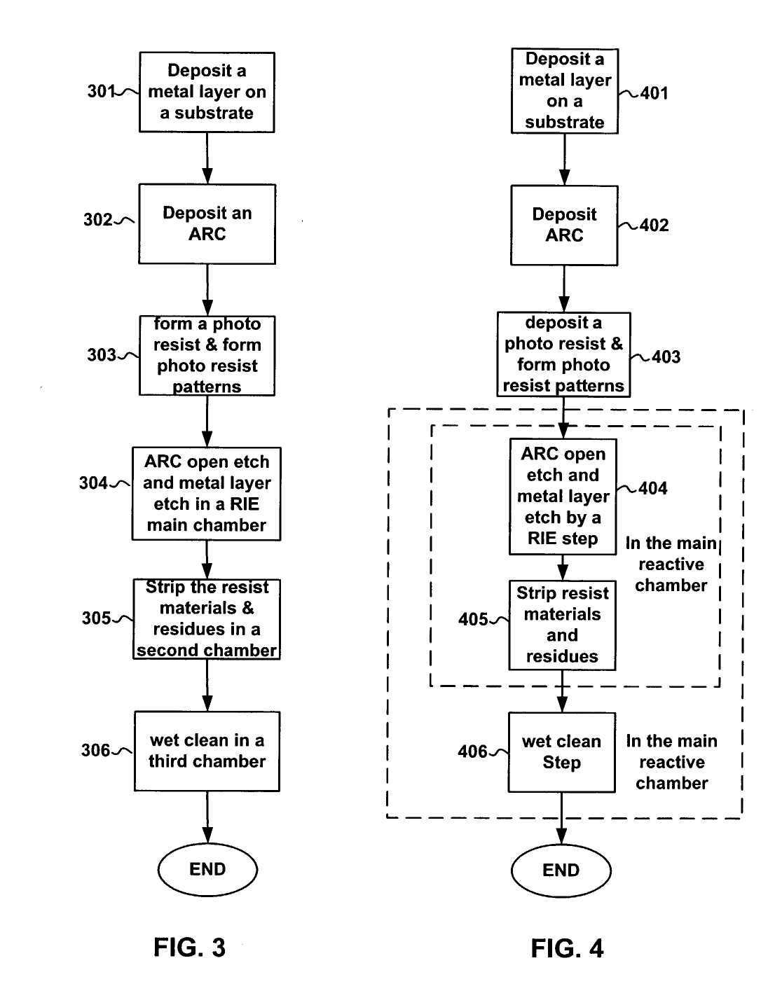

FIG. 4 is a flow chart of an Al RIE process in accordance with an embodiment of the present invention. It is noted that steps 401-403 are the same as steps 301-303, as previously described with reference to FIG. 3. Thus, a discussion of these steps is omitted here.

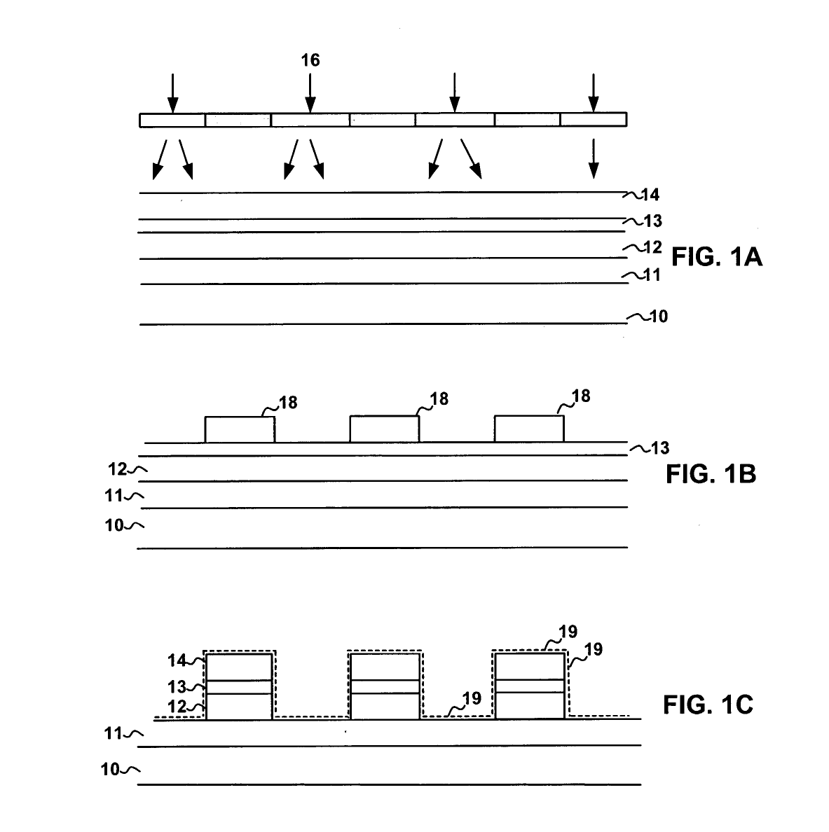

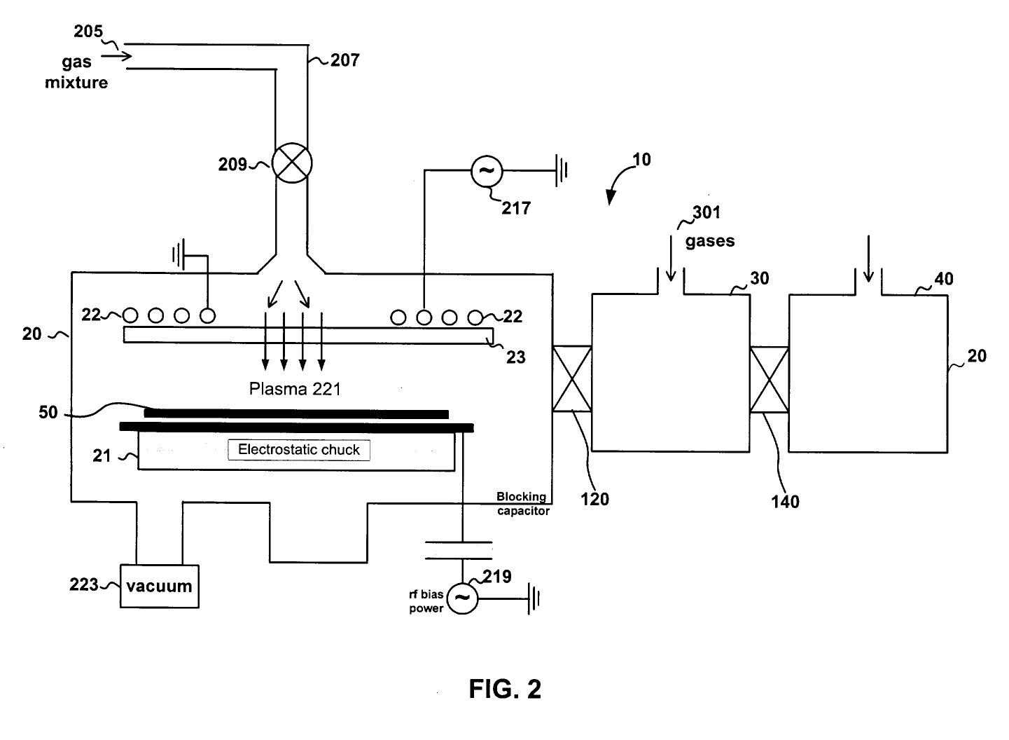

The wafer applied in the RIE process can be, but is not necessarily, manufactured according to the method as described in FIG. 1A and 1B. For example, it is not required to apply ARC 13 to the photoresist layer 14 if fine photoreist patterns can be formed in a photolithography process. For the purposes of explanation, however, the wafer described herein will be referred to as the one manufactured by the method with reference to FIG. 1A and 1B. The Al RIE tool described herein also will be referred to as that with reference to FIG. 2, except that in the embodiment of the present invention, reactive chamber 20 is used for performing both of the Al RIE step and the stripping step. Furthermore, the plasma reactor utilized in the reactive chamber 20 may be a different type than the inductively coupled plasma reactor, such as a traditional parallel-plate (diode-type) plasma reactor, negative-ion plasma reactor, parallel-plate dipole rotating magnet (DRM) reactor, chemical downstream (plasma) etching (CDE) system, and the like. The equivalent elements will be also referred to the same reference numbers.

In step 404, after photoresist patterns have formed, a wafer is transferred to an Al RIE main reactive chamber 20 as shown in FIG. 2 for an ARC open etching and an Al RIE step. As described above, the ARC open etching can be done in a separate plasma etching chamber. In the exemplary embodiment, the ARC open etching step is performed in the Al RIE main reactive chamber 20. The details of the ARC open etching is not described below. In the Al RIE step, the used gases can be any gases used in the conventional RIE process, for example, Cl₂/HCl, Cl₂/N₂, Cl₂/BCl₃, and the like.

As described above, due to the selected etching gases, during and after the RIE process, polymers 19 containing organic materials from the photoresist 14 and the ARC 13 (“resist materials”), and chlorine and/or chlorine-containing residues from the etching gases are all formed at the top of the photoresist and sidewalls of etched metal lines.

According to an embodiment of the present invention, after the RIE step, the wafer will not be transferred to a second chamber. Instead, the wafer remains in the main reactive chamber 20.

Next, in step 405, gases used as stripping compounds are introduced into the main reactive chamber 20 and the stripping step for stripping the polymer 19 and the resist materials is performed. The stripping process can be performed by using a gas mixture or by using plasma of a mixed gas.

With reference to step 405, as described above, corrosion of Al lines occurs when chlorine containing residues contacts with humidity in the atmosphere. To avoid this effect, an embodiment of the present invention keeps the water content in the main reactive chamber as low as possible. For this reason, one embodiment of the present invention may use load locks. The wafer with photoresist patterns can be first transferred to a load lock (not shown) attached to the main reactive chamber 20. The wafer is in “standby” in the load lock while a previous wafer is processed in the main reactive chamber 20, and then is transferred into the main reactive chamber when Al RIE step is completed for the previous wafer. To prevent from humidity, the load lock has to be maintained in a vacuum status. Furthermore, the present invention may apply BCl₃ as one of the etching component to help to reduce the humidity because it readily reacts with water. In accordance with another embodiment of the present invention, the pressure in main reactive chamber is kept very low to keep the chamber free of corrosion causing species. Moreover, in accordance with another embodiment of the present invention, the stripping compounds for stripping the resist materials and polymers 19 may comprise an Ar/O₂ gas mixture in different ratio combinations. Several examples of recipes used for stripping the resist materials and polymers 19 in accordance with the present invention will be described below.

Referring to FIG. 4, in step 406, after applying an appropriate recipe of stripping the resist materials and polymers as in step 405, a wet cleaning process is then carried out in a separate chamber such as chamber 40 in FIG. 2 to wash the stripping material away. Afterward, in step 407, the wafer is dried out by, for example, a spin-dryer. At this point, the entire Al RIE process is completed.

As is illustrated in FIG. 4, the RIE process in accordance with the present invention performs two major steps, such as the RIE step and the stripping step, in the main reactive chamber 20. In this manner, the wafer does not need to be transferred into a second chamber for performing the stripping step. Therefore, the cost of the second chamber is omitted. Further, the pressure within the reactive main chamber 20 is kept as low as possible, the chance that the wafer contacts with humidity in a separate chamber (such as second chamber 30 in FIG. 2) can be reduced.

In accordance with the present invention, a main reactive chamber performs both the Al RIE step and the stripping step. Therefore, an Al RIE tool in one embodiment of the present invention may be similar to the tool shown in FIG. 2 except that no second chamber 30 is needed, since the Al RIE step and the stripping step are both carried out in the main reactive chamber 20.

The main reactive chamber must be designed to enable the performance of the RIE step and the stripping step within a single unit. Separate gas inlets may be utilized for introducing different reactive gases necessary for performing the Al RIE step and the stripping step. The system may also comprise a pressure controller for controlling the pressure of the main reactive chamber. For example, different pressures are required for performing the Al RIE step and the stripping step.

Additionally, the system may include controllers for controlling the top supply power 217 and the bias supply power 219. Again, different supply powers are required for performing the Al RIE step and the stripping step. The system may also comprise several slots in the main chamber for connecting with various reactive gas sources to provide appropriate gas mixtures. The statuses of the introduced reactive gases, the pressure and the supply powers may be controlled by software. The examples of the reactive gases, the pressures and the supply powers will be described below.

As in the present invention, where the Al RIE step and the stripping step are performed in the main reactive chamber 20, the compounds and objective factors (such as the pressure in the main reactive chamber 20 and the top and bias supply powers supplied to the main reactive chamber 20) used in the stripping step are different from those in a conventional second chamber. For example, the density of oxygen used in conventional separate stripping chamber is controlled to be as low as possible, to avoid from reacting with the chlorine-containing residues. In this manner, it takes longer to completely remove the chlorine-containing residues. When performing the stripping step in the main reactive chamber in accordance with the present invention, however, the concentration of oxygen can be increased to ensure that the chlorine-containing residues are removed completely. Furthermore, the top supply power 217 and the bias supply power 219 in the main reactive chamber 20 can be controlled to facilitate a determination of the ion concentration and the energy of ions attacked on the wafer in the stripping gas mixture to completely remove the chlorine-containing residues. Therefore, the stripping step in accordance with the present invention is more efficient than that in the conventional stripping chamber, such as in a downstream reactor.

The followings are several examples which can be used in the main reactive chamber 20 for stripping the resist materials and polymers in accordance with the present invention:

### EXAMPLE 1

A typical recipe used for ARC open etching which has been used in a second chamber after the Al RIE process in the conventional art also can be utilized in the main reactive chamber for stripping the resist materials and residues according to a first embodiment of the present invention. By utilizing this recipe, 40 to 80 nm of organic ARC can be etched away within 10 to 60 seconds.

The first recipe is as follows:

The pressure of the RIE reactive chamber 20 is controlled in the range of 10 to 100 mTorr. The top power 217 is in the range of 100 to 300 W. The bias power 219 is in the range of 100 to 300 W. The gas is a Ar/O₂ mixture including 30 to 300 sccm of Ar and 3 to 20 sccm of O₂.

### EXAMPLE 2

For ARC open processes, the oxygen concentration is usually comparably low in order to prevent lateral attack of the organic ARC. However, when oxygen concentration is maintained to be very low, by using the same recipe for the ARC open etching in the stripping step, it will take longer to strip away the polymers completely. Therefore, in the second embodiment of the present invention, as the stripping process is carried out in the main reactive chamber without transferring the wafer to a second chamber, it is beneficial to increase the oxygen concentration either by increasing the oxygen flow, or decreasing Ar flow or by doing both at the same time so as to ensure complete stripping of the polymers. In some cases, even Ar-free etch conditions should lead to good results. Therefore, a modified set of etch parameters is as follows:

The pressure of the RIE reactive chamber 20 is controlled in the range of 10 to 100 mTorr. The top power 217 is in the range of 100 to 300 W. The bias power 219 is in the range of 100 to 300 W. The gas is a Ar/O₂ mixture including 0 to 300 sccm of Ar and 3 to 300 sccm of O₂.

### EXAMPLE 3

The ARC open etch usually is run at comparably low pressure in order to obtain straight side walls (i.e., an anisotropic etching). Based upon the same reason that the stripping process is now carried out in the main reactive chamber rather in a separate chamber, the pressure in the main reactive chamber can be increased, since this also increases oxygen concentration. Therefore, an in situ strip recipe with optimized pressure range in the third embodiment of the present invention is as follows:

The pressure of the RIE reactive chamber 20 is controlled in the range of 10 to 500 mTorr. The top power 217 is in the range of 100 to 300 W. The bias power 219 is in the range of 100 to 300 W. The gas is a Ar/O₂ mixture including 0 to 300 sccm of Ar and 3 to 300 sccm of O₂.

### EXAMPLE 4

Another embodiment in accordance with the present invention is to reduce the bias power and increase the top power. As described above, the bias power mainly determines the energy of ions that hit the wafer. The higher bias power therefore determines the direction of the ion attack and also helps to achieve an anisotropic attack in the etching step. In the stripping step, however, the ion bombardment has to be kept rather low. If the ion bombardment is too high after the Al RIE process, it could lead to damages of the Al lines just formed or even to the wafer in general. To avoid this, the present invention provides a lower bias power or even no bias power at all to the main reactive chamber.

Alternatively, in cases with no or very low bias power, it may be beneficial to increase the top power which mainly determines the ion concentration and thereby also the concentration of active species in general. As long as those species are not accelerated with high energies into the direction of the wafer, a higher concentration of these species reduces striping times and also helps to remove resistant residues.

Alternatively, the present invention allows to separately adjust the top and bias powers in order to fine tune the stripping conditions.

The stripping recipe in accordance with this embodiment can be as follows:

The pressure of the RIE reactive chamber 20 is controlled in the range of 10 to 500 mTorr. The top power 217 is in the range of 100 to 500 W. The bias power 219 is in the range of 0 to 50 W. The gas is a Ar/O₂ mixture including 0 to 300 sccm of Ar and 3 to 300 seem of O₂.

### EXAMPLE 5

In yet another embodiment of the present invention, the stripping condition can be improved is to change the strip chemistry. For example, the stripping compound can comprise an addition of F containing gases (like CF₄ or SF₆) to enhance the stripping process. The stripping compound can also comprises H₂ or hydrogen containing gases like H₂O. These additional chemical compound is helpful to further improve the strip results (i.e., more complete removal of all organic residues in less time).

Accordingly, one example of the stripping recipe can be as follows:

The pressure of the RIE reactive chamber 20 is controlled in the range of 10 to 500 mTorr. The top power 217 is in the range of 100 to 500 W. The bias power is in the range of 0 to 50 W. The gas is a Ar/O₂/CF₄ mixture including 0 to 300 scem of Ar, 3 to 300 seem of O₂ and 4 to 100 seem of CF₄.

The foregoing disclosure of the preferred embodiments of the present invention has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims appended hereto, and by their equivalents.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

What is claimed is:

1. A method for performing a metal reactive ion etching process, comprising:
depositing a semiconductor wafer in a main reactive chamber wherein the semiconductor wafer includes a metal layer on a wafer substrate and a photoresist covering the metal layer;
reactive-ion etching a metal layer formed on a semiconductor wafer in the main reactive chamber to form metal lines by etching away portions of the metal layer that are not covered by the photoresist; and
stripping away the photoresist and residues generated during the reactive-ion etching process, while maintaining the semiconductor wafer in the main reactive chamber.

2. The method of claim 1, wherein a gas mixture containing argon (Ar) and oxygen (O₂) is introduced into the main reactive chamber during the stripping step.

3. The method of claim 2, wherein the gas mixture comprises Ar of a concentration in the range of 0-300 sccm and O₂ of a concentration in the range of 3-20 sccm.

4. The method of claim 2, wherein pressure of the main reactive chamber is set in the range of 10-100 mTorr during the stripping step.

5. The method of claim 4, wherein a top power and a bias power supplied to the main reactive chamber are both between 100-300 W during the stripping step.

6. The method of claim 2, wherein the gas mixture comprises Ar of a concentration in the range of 0-300 sccm and O₂ of a concentration in the range of 3-300 sccm.

7. The method of claim 6, wherein pressure of the main reactive chamber during the stripping step is maintained in the range of 10-500 mTorr.

8. The method of claim 7, wherein a top power and a bias power supplied to the main reactive chamber during the stripping step are both between 100-300 W.

9. The method of claim 7, wherein a top power and a bias power supplied to the main reactive chamber during the stripping step are 100-500 W and 0-50 W, respectively.

10. The method of claim 9, further comprising a CF₄ gas of 3-300 sccm.

11. A system for performing a metal reactive ion etching process, comprising:
a main reactive chamber for performing a metal etching step and a stripping step for a wafer having a metal layer and photoresist patterns on a surface of the metal layer; and
at least one gas inlet to the main reactive chamber adapted for introducing a first set of reactive gases used for the metal etching step and a second set of reactive gases used for the stripping step.

12. The system of claim 11, wherein the reactive gases introduced from the at least one inlet are processed by a pair of electrodes in the main reactive chamber to form plasma therebetween, and reactive ions of the plasma react with portions of the metal layer that are not covered by the photoresist patterns.

13. The system of claim 12, wherein the pair of electrodes comprises a top electrode and a bottom electrode, and wherein during the stripping step, a top power supply provides a first power to the top electrode to determine an ion concentration of the reactive ions and a bias power supply provides a second power to the bottom electrode to determine a moving direction of the reactive ions.

14. The system of claim 11, further comprising:
a pressure controller for setting different pressures of the main reactive chamber based upon the reactive gases used for the metal etching and the stripping step.

15. A method for stripping residues after a metal reactive ion etching process in a main reactive chamber, wherein the residues are by-products remaining on metal lines formed by the metal reactive ion etching process, the method comprising:
adjusting a pressure of the main reactive chamber;
adjusting a top power and a bias power supplied to the main reactive chamber; and
applying gas mixtures into the main chamber that are reactive with the residues,
wherein the pressure, the top power and the bias power are adjusted such that the gas mixtures react with the residues to strip away the residues without reacting with the metal lines, and
wherein the metal reactive ion etching process is also performed in the main reactive chamber.

16. The method of claim 15, wherein the pressure of the main chamber is maintained in the range of 10-100 Torr.

17. The method of claim 15, wherein the top bias power and the bias power supplied to the main chamber are both between 100-300 W.

18. The method of claim 15, wherein the gas mixture comprises Ar of a concentration in the range of 0-300 sccm and O₂ of a concentration in the range of 3-300 sccm.

19. The method of claim 18, wherein the pressure of the main reactive chamber is maintained in the range of 10-500 mTorr.

20. The method of claim 19, further comprising a CF₄ gas of 3-300 sccm.
